(19) United States
(12) Patent Application Publication
(10) Pub. No.: US 2024/0363369 A1
(43) Pub. Date: Oct. 31, 2024

(54) MODULAR ELECTRONICS FOR FLOW CONTROL

(71) Applicant: Ichor Systems, Inc., Fremont, CA (US)

(72) Inventors: Philip Ryan Barros, Pleasanton, CA (US); Greg Patrick Mulligan, Milpitas, CA (US); Sean Joseph Penley, Sparks, NV (US); Christopher Bryant Davis, Georgetown, TX (US)

(21) Appl. No.: 18/643,863

(22) Filed: Apr. 23, 2024

Related U.S. Application Data
(60) Provisional application No. 63/498,190, filed on Apr. 25, 2023.

(51) Int. Cl. H01L 21/67

(52) U.S. Cl. CPC H01L 21/67023; H01L 21/67253; H01L 21/67276

(57) ABSTRACT

Systems for manufacturing semiconductors are essential to enabling modern technologies. Such systems may include a central controller, a plurality of fluid supplies, a plurality of apparatus for controlling flow, and a processing chamber. The central controller may have a processor, a memory, and a communication module. The plurality of apparatus for controlling flow may have a device controller having an active component, a sensor, and a communication module. The communication may have a communication module, a memory, a sensor drive circuit operably coupled to the sensor, and an active component drive operably coupled to the active component. The central controller is configured to receive sensor data from the sensors of the plurality of apparatus for controlling flow and transmit active component commands to the active component drives of the device controllers to control the plurality of apparatus for controlling flow.

### CROSS-REFERENCE TO RELATED APPLICATIONS

This application claims the benefit of U.S. Provisional Application 63/498,190, filed Apr. 25, 2023, which is incorporated herein by reference in its entirety.

### BACKGROUND

Systems and devices for semiconductor processing utilize a variety of electronic control strategies. Semiconductor fabrication processes require a plurality of apparatus for controlling flow which control and dispense a wide array of fluids, including numerous gases and liquids. Each apparatus for controlling flow must be controlled to enable complex processing steps. The required control of the apparatus for controlling flow may be implemented locally on the apparatus for controlling flow, implemented in individual active components of the apparatus for controlling flow, or implemented in a central controller which directly controls the apparatus for controlling flow or active components of the apparatus for controlling flow.

Current systems suffer from costly control strategies requiring specialized solutions for each apparatus for controlling flow. As systems increase in size and complexity, development costs and time increase. Reducing cost, improving reliability, enabling increased capabilities, and maintaining minimal complexity are desired. It is further desired to reduce the cost and improve serviceability of systems and devices for semiconductor processing. Improvements in systems and devices for semiconductor processing are desired to enable improved functionality while reducing cost and complexity.

### SUMMARY

The present technology is directed to systems for manufacturing semiconductor devices and associated methods. These systems rely on various types of control electronics which may be designed in a variety of ways. Currently available systems implement many custom electronics modules for semiconductor manufacturing systems and apparatus for controlling flow, these modules often being highly specialized for a particular system. Such systems may be used to implement a wide range of processes such as semiconductor chip fabrication, solar panel fabrication, and the like.

In one implementation, the invention is a system for manufacturing semiconductors having a central controller, a plurality of fluid supplies, a plurality of apparatus for controlling flow, and a processing chamber. The central controller has a processor, a memory, and a communication module. Each of the plurality of apparatus for controlling flow have an inlet fluidly coupled to one of the plurality of fluid supplies, an outlet, a fluid pathway connecting the inlet to the outlet, a sensor fluidly coupled to the fluid pathway, an active component fluidly coupled to the fluid pathway, and a device controller having a communication module, a memory, a sensor circuit operably coupled to the sensor, and an active component drive operably coupled to the active component. The processing chamber is fluidly coupled to the outlets of the plurality of apparatus for controlling flow, the processing chamber configured to contain an article to be processed. The central controller is configured to receive sensor data from the sensor circuit of a first one of the plurality of apparatus for controlling flow and transmit an active component command to the active component drive of the first one of the plurality of apparatus for controlling flow, the active component command computed based on the sensor data.

In another implementation, the invention is a system for manufacturing semiconductors having a central controller, a fluid supply, a first apparatus for controlling flow, a processing chamber, and a communication bus. The central controller has a processor, a memory, and a communication module. The first apparatus for controlling flow has an inlet fluidly coupled to the fluid supply, an outlet, a fluid pathway connecting the inlet to the outlet, a sensor fluidly coupled to the fluid pathway, an active component fluidly coupled to the fluid pathway, and a device controller having a communication module, a memory, a sensor circuit operably coupled to the sensor, and an active component drive operably coupled to the active component. The processing chamber is fluidly coupled to the outlet of the first apparatus for controlling flow, the processing chamber configured to contain an article to be processed. The communication bus is operatively connecting the communication module of the central controller and the communication module of the device controller. The device controller is configured to transmit a sensor data message containing sensor data to the central controller via the communication bus. The central controller is configured to transmit an active component message to the device controller via the communication bus, the active component message containing an active component command determined at least in part based on a setpoint stored in the memory of the central controller and on the sensor data of the sensor data message.

In yet another implementation, the invention is a system for manufacturing semiconductors having a central controller, a fluid supply, a first apparatus for controlling flow, a processing chamber, and a communication bus. The central controller has a processor, a memory, and a communication module. The first apparatus for controlling flow has an inlet fluidly coupled to the fluid supply, an outlet, a fluid pathway connecting the inlet to the outlet, a sensor fluidly coupled to the fluid pathway, an active component fluidly coupled to the fluid pathway, and a device controller having a communication module, a memory, a sensor circuit operably coupled to the sensor, and an active component drive operably coupled to the active component. The processing chamber is fluidly coupled to the outlet of the first apparatus for controlling flow, the processing chamber configured to contain an article to be processed. The communication bus is operatively connecting the communication module of the central controller and the communication module of the device controller. The device controller is configured to transmit a sensor data message containing sensor data to the central controller via the communication bus. The central controller implements a feedback control loop utilizing sensor data from the first apparatus for controlling flow to control the active component of the first apparatus for controlling flow.

In a further implementation, the invention is a method of manufacturing semiconductors. In a first step, a first sensor data message containing first sensor data is transmitted from a device controller of a first apparatus for controlling flow to a central controller, the first apparatus for controlling flow having a sensor operably coupled to the device controller, the sensor sensing a characteristic of a fluid within a fluid pathway of the first apparatus for controlling flow. In a second step, a first active component command is computed using a setpoint stored in a memory of the central controller and the first sensor data of the first sensor data message. In a third step, a first active component message is transmitted from the central controller to the device controller of the first apparatus for controlling flow, the first active component message containing the first active component command. In a fourth step, an active component of the first apparatus for controlling flow is controlled in accordance with the first active component command to deliver the fluid to a processing chamber containing an article to be processed. In a fifth step, a second sensor data message containing second sensor data is transmitted from the device controller of the first apparatus for controlling flow to the central controller. In a sixth step, a second active component command is computed using the setpoint and the second sensor data. In a seventh step, a second active component message is transmitted from the central controller to the device controller of the first apparatus for controlling flow, the second active component message containing the second active component command. In an eighth step, the active component is controlled in accordance with the second active component command to deliver the fluid to the processing chamber.

In another implementation, the invention is a system for manufacturing semiconductors having a central controller, a fluid supply, a first apparatus for controlling flow, a second apparatus for controlling flow, and a processing chamber. The central controller has a processor, a memory, and a communication module. The first apparatus for controlling flow has an inlet fluidly coupled to the fluid supply, an outlet, a fluid pathway connecting the inlet to the outlet, a sensor fluidly coupled to the fluid pathway, and a device controller having a communication module, a memory, and a sensor circuit operably coupled to the sensor. The second apparatus for controlling flow has an inlet fluidly coupled to the fluid supply, an outlet, a fluid pathway connecting the inlet to the outlet, an active component fluidly coupled to the fluid pathway, and a device controller having a communication module, a memory, and an active component drive operably coupled to the active component. The processing chamber is fluidly coupled to the outlet of the first and second apparatus for controlling flow, the processing chamber configured to contain an article to be processed. The device controller of the first apparatus for controlling flow is configured to transmit a sensor data message containing sensor data to the central controller. The central controller is configured to transmit an active component message to the device controller of the second apparatus for controlling flow, the active component message containing an active component command determined at least in part based on a setpoint stored in the memory of the central controller and on the sensor data of the sensor data message.

In yet another implementation, the invention is a method for manufacturing semiconductors. In a first step, a first fluid is flowed through a first apparatus for controlling flow and a second fluid is flowed through a second apparatus for controlling flow, the first and second fluids delivered from the first and second apparatus for controlling flow to a processing chamber containing an article to be processed. In a second step, first and second sensor data is transmitted from the first and second apparatus for controlling flow to a central controller, the first and second sensor data indicative of a characteristic of the first and second fluids flowing through the first and second apparatus for controlling flow. In a third step, first and second active component commands are computed in the central controller using the first and second sensor data. In a fourth step, the first and second active component commands are transmitted from the central controller to the first and second apparatus for controlling flow. In a fifth step, active components of the first and second apparatus for controlling flow are controlled in accordance with the first and second active component commands. In a sixth step, first and second sensor data from the first and second apparatus for controlling flow are transmitted to the central controller. In a seventh step, the second active component command is recomputed using the first sensor data. In an eighth step, the second active component command is retransmitted from the central controller to the second apparatus for controlling flow. In a ninth step, the active component of the second apparatus for controlling flow is controlled in accordance with the second active component command.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The present invention will become more fully understood from the detailed description and the accompanying drawings, wherein:

FIG. 1 is a schematic of a processing system for manufacturing semiconductor devices utilizing one or more apparatuses for controlling flow.

FIG. 2 is a schematic of a mass flow controller, the mass flow controller being one of the apparatuses for controlling flow as may be utilized in the system of FIG. 1.

FIG. 3 is a schematic of an alternate configuration of a mass flow controller as may be utilized in the system of FIG. 1.

FIG. 4 is a block diagram illustrating a control system as may be utilized in the system of FIG. 1.

FIG. 5 is a block diagram illustrating another embodiment of a control system as may be utilized in the system of FIG. 1.

FIG. 6 is a block diagram illustrating another embodiment of a control system as may be utilized in the system of FIG. 1.

FIG. 7 is a flow chart illustrating a method of manufacturing semiconductors.

FIG. 8 is a flow chart illustrating another method of manufacturing semiconductors.

All drawings are schematic and not necessarily to scale. Features shown numbered in certain figures which may appear un-numbered in other figures are the same features unless noted otherwise herein.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication module devices including Wi-Fi, Bluetooth, LAN, etc.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present invention may be embodied in the form of computer-implemented processes and apparatuses such as processor-based data processing and communication systems or computer systems for practicing those processes. The present invention may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

In the following description, where circuits are shown and described, one of skill in the art will recognize that, for the sake of clarity, not all peripheral circuits or components are shown in the figures or described in the description. Further, the terms “couple” and “operably couple” can refer to a direct or indirect coupling of two components of a circuit.

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and other similar terms refer to a relationship wherein structures are secured or attached to one another either directly or indirectly through intervening structures, as well as both movable or rigid attachments or relationships, unless expressly described otherwise. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

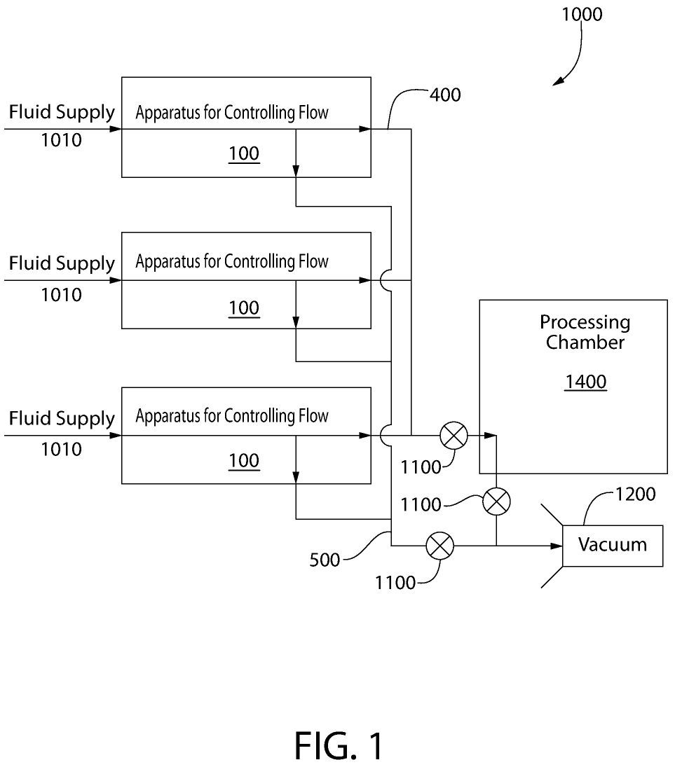

FIG. 1 shows a schematic of an exemplary processing system 1000 for processing articles. The processing system 1000 may utilize a plurality of apparatus for controlling flow 100 fluidly coupled to a processing chamber 1300. Each of the plurality of apparatus for controlling flow 100 has a fluid supply 1010 fluidly coupled thereto, each of the fluid supplies 1010 supplying a process fluid to their respective apparatuses for controlling flow 100. Optionally, a plurality of fluid supplies 1010 may be fluidly coupled to a single apparatus for controlling flow 100 or a plurality of apparatuses for controlling flow 100 may be fluidly coupled to a single fluid supply 1010. Each of the fluid supplies 1010 may deliver a different process fluid or a portion of the fluid supplies 1010 may deliver a single process fluid.

The plurality of apparatus for controlling flow 100 are used to supply one or more different process fluids to the processing chamber 1300 via an outlet manifold 400. Articles such as semiconductors may be processed within the processing chamber 1300. A valve 1100 isolates the apparatuses for controlling flow 100 from the processing chamber 1300, enabling the apparatuses for controlling flow 100 to be selectively connected or isolated from the processing chamber 1300. The processing chamber 1300 may contain one or more applicators to apply process fluids delivered by the plurality of apparatus for controlling flow 100, enabling selective or diffuse distribution of the fluid supplied by the plurality of apparatus for controlling flow 100.

In addition, the processing system 1000 may further comprise a vacuum source 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Each of the apparatuses for controlling flow 100 may have a separate bleed port which is coupled to a vent manifold 500, the vent manifold 500 connected to the vacuum source 1200 via a valve 1100. Optionally, the apparatuses for controlling flow 100 may be mass flow controllers, flow splitters, or any other device which controls the flow of a process fluid in a processing system for processing semiconductor devices such as semiconductor chips, solar panels, or the like. Furthermore, valves 1100 may be integrated into the apparatus for controlling flow 100 if so desired. In some implementations this may eliminate the need for certain other valves 1100 in the processing system 1000.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, or any other process utilizing controlled volumes of a process fluid.

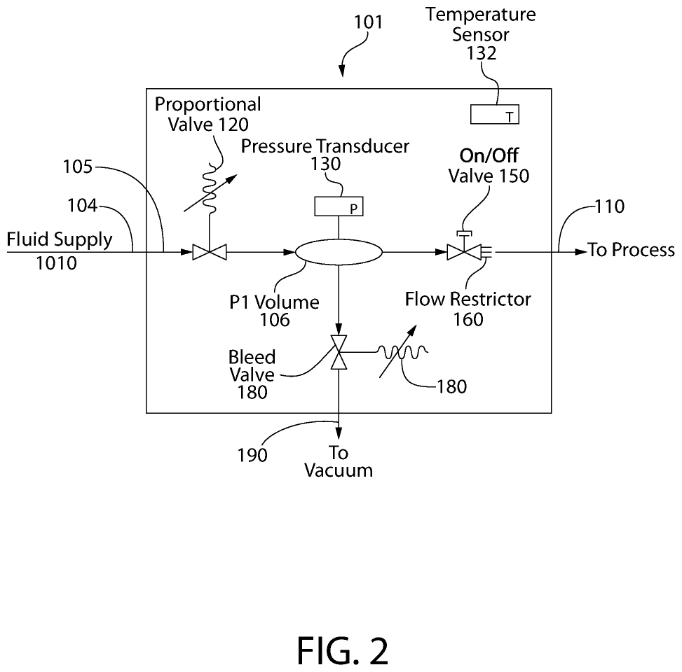

FIG. 2 shows a schematic of an exemplary mass flow controller 101, which is one type of apparatus for controlling flow 100 that may be utilized in the processing system 1000. The mass flow controller 101 has a fluid supply 1010 of a process fluid fluidly coupled to an inlet 104. A fluid pathway 105 extends from the inlet 104 to an outlet 110, the outlet 110 fluidly coupled to the outlet manifold 400. The inlet 104 is fluidly coupled to a proportional valve 120 which is capable of varying the mass and volume of process fluid flowing through the proportional valve 120. The proportional valve 120 meters the mass flow of process fluid which passes to a P1 volume 106. The proportional valve 120 is capable of providing proportional control of the process fluid such that it need not be fully open or closed, but instead may have intermediate states to permit control of the mass flow rate of process fluid.

The P1 volume 106 is fluidly coupled to the proportional valve 120, the P1 volume 106 being the sum of all the volume within the mass flow controller 101 between the proportional valve 120 and a flow restrictor 160. A pressure transducer 130 is fluidly coupled to the P1 volume 106 to enable measurement of the pressure within the P1 volume 106. A shutoff valve 150 is located between the flow restrictor 160 and the proportional valve 120 and may be used to completely halt flow of the process fluid out of the P1 volume 106. Optionally, the flow restrictor 160 may be located between the shutoff valve 150 and the proportional valve 120 in an alternate configuration. The flow restrictor 160 is fluidly coupled to the outlet 110 of the mass flow controller 101. In the processing system, the outlet 110 is fluidly coupled to a valve 1100 or directly to the processing chamber 1300. In the present embodiment, the flow restrictor 160 is located between the shutoff valve 150 and the outlet 110. In an alternate embodiment, the shutoff valve 150 is located between the flow restrictor 160 and the outlet 110. Thus, the arrangement of the shutoff valve 150 and the flow restrictor 160 may be reversed.

Finally, a bleed valve 180 is coupled to the P1 volume 106 and to a bleed port 190. In the present example, the bleed valve 180 is a proportional valve. The bleed valve 180 may also be an on/off valve or any other type of valve suitable for controlling fluid flow. Optionally, a second flow restrictor 160 may be incorporated between the P1 volume and the bleed port 190. A proportional valve, if used as the bleed valve 180, enables control over a rate of fluid flow through the bleed port 190. A characterized restrictor 160 may aid in improving control over the rate of fluid flow, regardless of whether the bleed valve 180 is a proportional valve or an on/off valve. Preferably, the rate of fluid flow through the bleed valve 180 is characterized so that the flow rate can be estimated for a given state of the bleed valve 180.

Internal to the first shutoff valve 150 is a valve seat and a closure member. When the apparatus 100 is delivering process fluid, the first shutoff valve 150 is in an open state, such that the valve seat and the closure member are not in contact. This permits flow of the process fluid and provides a negligible restriction to fluid flow. When the first shutoff valve 150 is in a closed state the closure member and the valve seat are biased into contact by a spring, stopping the flow of process fluid through the first shutoff valve 150.

The flow restrictor 160 is used, in combination with the proportional valve 120, to meter flow of the process fluid. In most embodiments, the flow restrictor 160 provides a known restriction to fluid flow. The first characterized flow restrictor 160 may be selected to have a specific flow impedance so as to deliver a desired range of mass flow rates of a given process fluid. The flow restrictor 160 has a greater resistance to flow than the passages upstream and downstream of the flow restrictor 160.

Optionally, the mass flow controller 101 comprises one or more P2 pressure transducers downstream of the flow restrictor 160 and the shutoff valve 150. The P2 pressure transducer is used to measure the pressure differential across the flow restrictor 160. In some embodiments, the P2 pressure downstream of the flow restrictor 160 may be obtained from another apparatus 100 connected to the processing chamber, with the readings communicated to the mass flow controller 101.

Optionally, one or more temperature sensors 132 may be employed to further enhance the accuracy of the mass flow controller 101. They may be mounted in the base of the mass flow controller 101 near the P1 volume 106. Additional temperature sensors 132 may be employed in a variety of locations, including adjacent the proportional valve 120, the pressure transducer 130, the shutoff valve 150, and the bleed valve 180.

The proportional valve 120, the shutoff valve 150, and the bleed valve 180 may be referred to as active components because they are actively controlled to achieve the desired control of fluids through the plurality of apparatus for controlling flow 100. The active components need not be valves, and may also include devices which selectively restrict flow, or otherwise alter a characteristic of the fluid flowing through the apparatus for controlling flow. Other types of active components may be flow regulators, transducers, or actuators.

The pressure transducer 130 and the temperature sensors may be referred to as sensors because they detect or sense a characteristic of a fluid within a fluid pathway 105 of the plurality of apparatus for controlling flow 100. In other implementations, the pressure transducer 130 or the temperature sensor 130 may be used to sense a characteristic of a fluid within the system, but external to the plurality of apparatus for controlling flow. For example, when two apparatus for controlling flow are fluidly coupled by the outlet manifold 400, a pressure within one apparatus for controlling flow can be measured by a pressure transducer located within a second apparatus for controlling flow. Other types of sensors may include transducers, flow sensors, accelerometers, gyroscopes, or any other known device for sensing a characteristic within the system including characteristics of the fluids or characteristics of the apparatus for controlling flow 100.

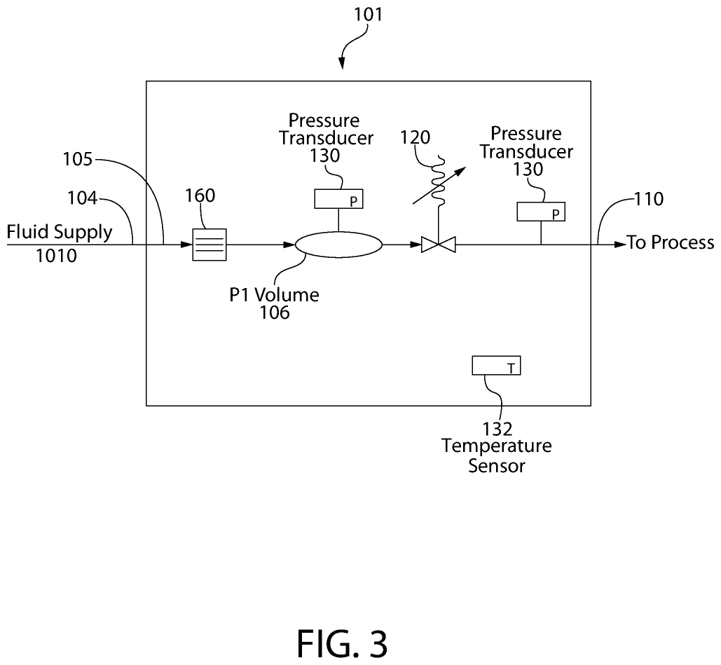

In other implementations, such as that shown in FIG. 3, the mass flow controller 101 may utilize an alternate configuration where the flow restrictor 160 is fluidly coupled to the inlet 104, the inlet 104 fluidly coupled to the fluid supply 1010. The flow restrictor 160 is fluidly coupled to the proportional valve 120, with the P1 volume 106 located between the flow restrictor 160 and the proportional valve 120. A first pressure transducer 130 is fluidly coupled to the P1 volume 106 so that it senses pressure within the P1 volume 106. A second pressure transducer 130 serves as a P2 pressure transducer to sense pressure between the proportional valve 120 and the outlet 110.

Optionally, a bleed valve 180 may be included or omitted in the mass flow controller 101 of FIG. 3. Further optionally, the second pressure transducer 130 may be omitted or located elsewhere. The proportional valve 120 may be substituted with an on/off valve, and the location of the proportional valve 120 and the flow restrictor 160 may be switched. The on/off valve 150 is omitted in this embodiment, but may be incorporated either before the flow restrictor 160, after the proportional valve 120, or in between the flow restrictor 160 and the flow proportional valve 120. In yet other implementations, the valve 1100 may be used in place of the on/off valve 150.

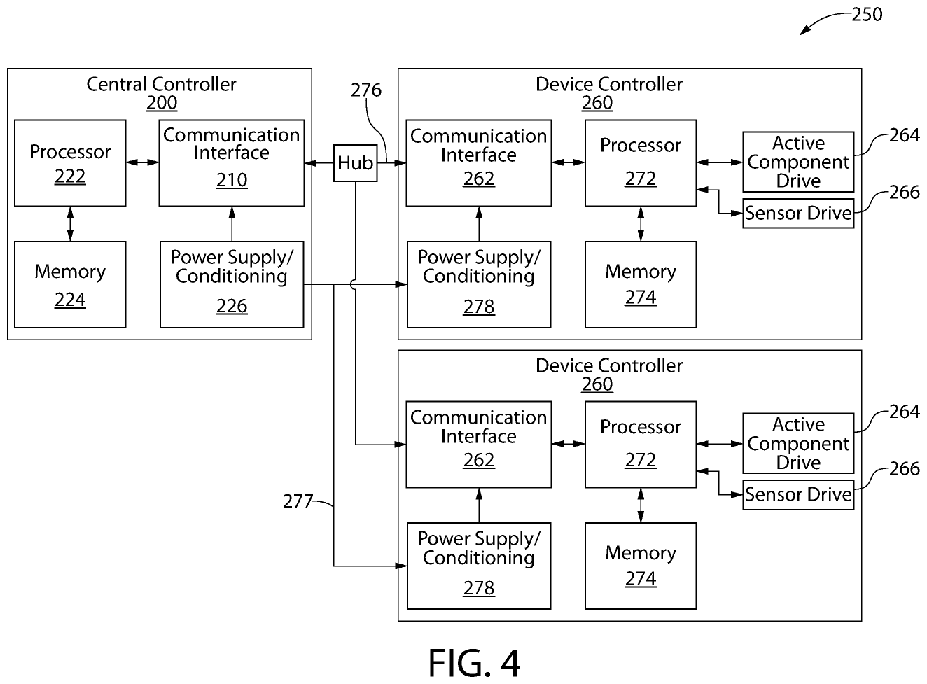

Turning to FIG. 4, a block diagram illustrates a controller 250 for the processing system 1000 of FIG. 1. This block diagram shows a device controller 260 and a central controller 200. The device controller 260 provides interface functions for an apparatus for controlling flow 100 within the processing system 1000 and enables control of the apparatus for controlling flow 100. The device controller 260 has a communication module 262, at least one active component drive 264, at least one sensor drive 266, a processor 272, memory 274, and a power supply/conditioning module 278.

Optionally, a single device controller 260 may operate a plurality of apparatuses for controlling flow 100 or each apparatus for controlling flow 100 may have a dedicated device controller 260, each of the device controllers 260 communicating with the central controller 200 and other apparatus controllers 260 via a communication bus 276. The communication module 262 is configured to provide a communications link between the apparatus controller 260 and the central controller 200. The communication module 262 may be configured to communicate with the central controller 200 and other device controllers 260 via the communication bus 276 as will be discussed in greater detail below.

The device controller 260 may utilize one or more active component drives 264 to enable control of active components such as the proportional valve 120, bleed valve 180, and on/off valve 150. The active component drives 264 may be valve drives or any other type of drive required to operate solenoids, piezoelectric devices, or other devices required to operate the active components. The active component drives 264 may enable proportional control or on/off control of valves or other active devices as desired. In some implementations, the active component drives 264 may be dedicated to specific types of active components or may be configured to be used with a variety of different types of active components.

The device controller 260 may also utilize one or more sensor drives 266, the sensor drives 266 configured to interface with the sensors of the apparatus for controlling flow 100. For example, the sensor drives 266 may be configured to generate sensor data from the pressure transducer 130 or a temperature sensor 132 of the mass flow controller 101. The sensor drives 266 may generate sensor data as analog data or may generate sensor data in a digital format. The sensor drives 266 may be configured for specific sensor types or may be configured to interface with a variety of different sensor types. For example, the device controller 260 may implement a single type of sensor drive 266 which can interface with both temperature sensors 132 and pressure transducers 130. Alternately, the device controller 260 may have dedicated sensor drives 266 for each type of sensor.

The processor 272 and the memory 274 of the device controller 260 may interface with the communication module 262, the sensor drive 266, and the active component drive 264. The memory 274 may store calibration data for the mass flow controller 101 or other apparatus for controlling flow 100, including the sensors and the active components. The memory 274 may further store setpoints for the mass flow controller 101 or other apparatus for controlling flow 100. In other configurations as will be discussed further below, the setpoints may be stored in other locations. The processor 272 may implement a control loop which relies on sensor data from the sensor drives 266 to control the active components of the mass flow controller 101 or other apparatus for controlling flow 100 via the active component drives 264. In other implementations, the control loop may be implemented external to the device controller 260.

The central controller 200 has a communication module 210, a processor 222, a memory 224, and a power supply/conditioning module 226. The central controller 200 coordinates functions necessary to perform desired processes on the semiconductor devices or other articles to be processed. The communication module 210 of the system controller 200 sends and receives commands through the communication bus 276. The communication bus 276 connects to the communication module 262 of one or more device controllers 260 operating one or more apparatus for controlling flow 100. The communication bus 276 may connect the central controller 200 to a single device controller 260, or it may connect to a plurality of device controllers 260. Each device controller 260 may operate a distinct apparatus for controlling flow 100 or a plurality of apparatus for controlling flow. In yet other implementations, some device controllers 260 may not control an apparatus for controlling gas flow 100. Instead, other types of process equipment may also be controlled by the device controller 101. Optionally, the communication bus 276 may incorporate a hub or other device which enables connection of all apparatus for controlling flow 100 required to complete a desired set of processes on an article to be processed. Furthermore, there may be a plurality of communication buses 276 to connect all the devices required to perform the desired process. In other implementations, the communication bus 276 may be substituted with a plurality of direct communications links between individual controllers 200, 260.

The communication bus 276 may be a serial bus, a parallel bus, or a combination of serial and parallel bus. Thus, the communication bus 276 may enable communication via one of a variety of protocols including serial communication protocols or parallel communication protocols. For example, the communication modules 210, 262 may transmit messages or other data packets using any one of a variety of protocols. For example, data may be transmitted as sensor data messages and active component messages, with the sensor data messages containing sensor data and the active component messages containing active component commands. Other types of messages such as setpoint messages may be transmitted via the communication bus 276, the setpoint messages containing desired setpoints for the apparatus for controlling flow 100. A variety of protocols may be used, including protocols using RS-232, RS-422, RS-485 or other standards. Other protocols may include Ethernet, EtherCAT, Modbus, Profibus, Profinet, DeviceNet, CANbus, Fieldbus, OPC, MQTT, BACnet, or any other known communications protocol or standard to enable communications between the central controller 200 and the device controllers 260.

A power connection 277 may be implemented, with the central controller 200 providing power from the power supply/conditioning module 226 of the central controller 200 to the power supply/conditioning modules 278 of the device controllers 260 via the power connection 277. In some implementations, the power connection 277 may be incorporated into the communication bus 276. In other implementations, power connections 277 may be provided from the central controller 200 to the device controllers 260 separately from the communication bus 276. Optionally, power may be transmitted over the communication bus 276 in a manner analogous to power over ethernet (“POE”) type systems where the communication bus is also a power bus.

The central controller 200 may be coupled to mains power, with the power supply/conditioning module 226 converting mains power to 12 to 24 volts DC. The power supply/conditioning modules 278 of the device controllers 260 may convert the supplied 12 to 24 volts DC from the power supply/conditioning module 226 to 3.3 volts, 5 volts, or 12 volts DC for direct use by device controller 260. The power supply/conditioning module 226 may also supply 3.3 volts, 5 volts, or 12 volts DC for use by the central controller 200. In other implementations, each of the device controllers 260 may be directly connected to mains power and the power supply/conditioning modules 278 may convert mains power directly to the required voltage levels for the device controllers 260.

The processor 222 and the memory 224 implement the desired processes on the articles to be processed, storing parameters and executing stored instructions required to operate the system 1000. For example, the memory 224 may store setpoints for a plurality of apparatus for controlling flow 100 and the processor may use the communication module 210 to transmit setpoint messages to the device controllers 260, the device controllers 260 controlling their active components based on sensor data from their sensors and setpoint data within the setpoint messages. Thus, a control loop may be implemented within the device controllers 260. Optionally, sensor data from other device controllers 260 of other apparatus for controlling flow 100 may also be used to control the active components. Thus, control of fluids may be achieved. For example, the system may deliver desired mass flow rates of gas or liquid at desired times and for desired durations as commanded by the central controller 200. The device controllers 260 may implement any required feedback control loops to control the active controllers.

In other implementations, the central controller 200 may store setpoint information in the memory 224 and the processor 222 may implement the required feedback control loops for all apparatus for controlling flow 100. Thus, sensor data messages from each of the device controllers 260 of the apparatus for controlling flow 100 may be transmitted to the central controller 200. Sensor data from the sensor data messages may be used, in combination with the setpoints stored in the memory 224, to compute active component commands and transmit active component messages to the device controllers 260. The device controllers 260 may then cause the active components to be controlled in accordance with the active component commands, new sensor data can be transmitted back to the central controller 200, and the active component commands can be recomputed and retransmitted to the device controllers 260. Thus, the feedback loop may be implemented in the central controller. It is further contemplated that some apparatus for controlling flow 100 may exclusively generate sensor data while other apparatus for controlling flow may exclusively incorporate active components, with sensor data from a first apparatus for controlling flow used to control an active component in a second apparatus for controlling flow. In yet other configurations, sensor data from a first and second apparatus for controlling flow may be used to compute the active component command for the first apparatus for controlling flow.

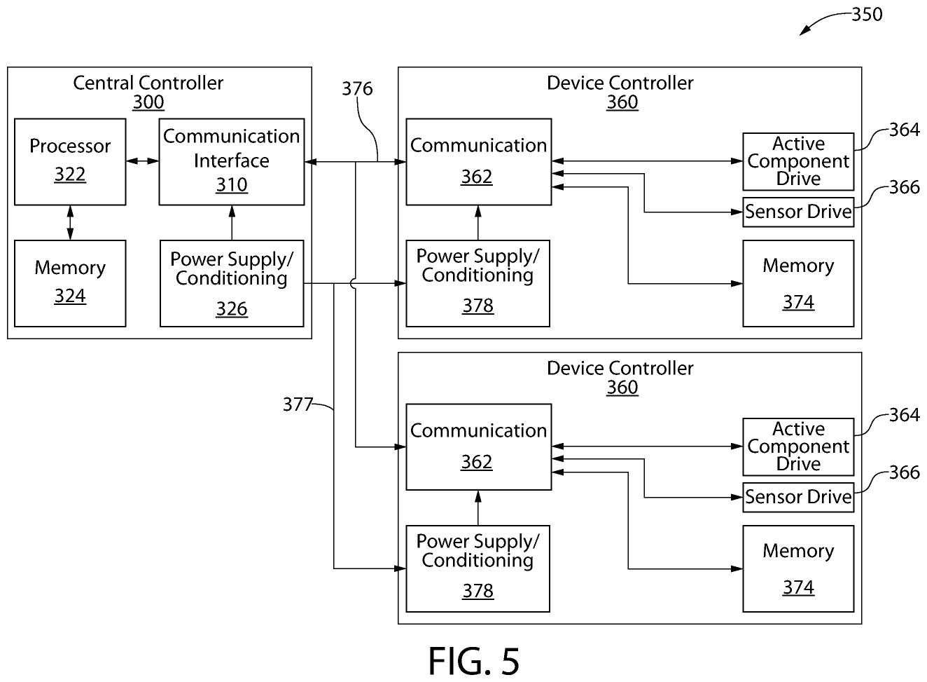

Turning to FIG. 5, another controller 350 having a central controller 300 and a plurality of device controllers 360 is illustrated. The central controller 300 has a processor 322, a memory 324, a communication module 310, and a power supply/conditioning module 326. A communication bus 376 and a power connection 377 link the central controller 300 to the plurality of device controllers 360. Optionally, each of the device controllers 360 may not implement a processor. The device controllers 360 may have a communication module 362, a memory 374, an active component drive 364, a sensor drive 366, and a power supply/conditioning module 378. Thus, sensor data is passed directly from the sensor drive 366 to the communication module 362. Similarly, active component commands are passed directly from the communication module 362 to the active component drive 364. As above, it is contemplated that sensor data from different apparatus for controlling flow 100 may be combined to compute the active component command for a single apparatus for controlling flow 100, and that not all apparatus for controlling flow 100 may incorporate both a sensor and an active component. Calibration values for the sensors and active components may be stored in the memory 374.

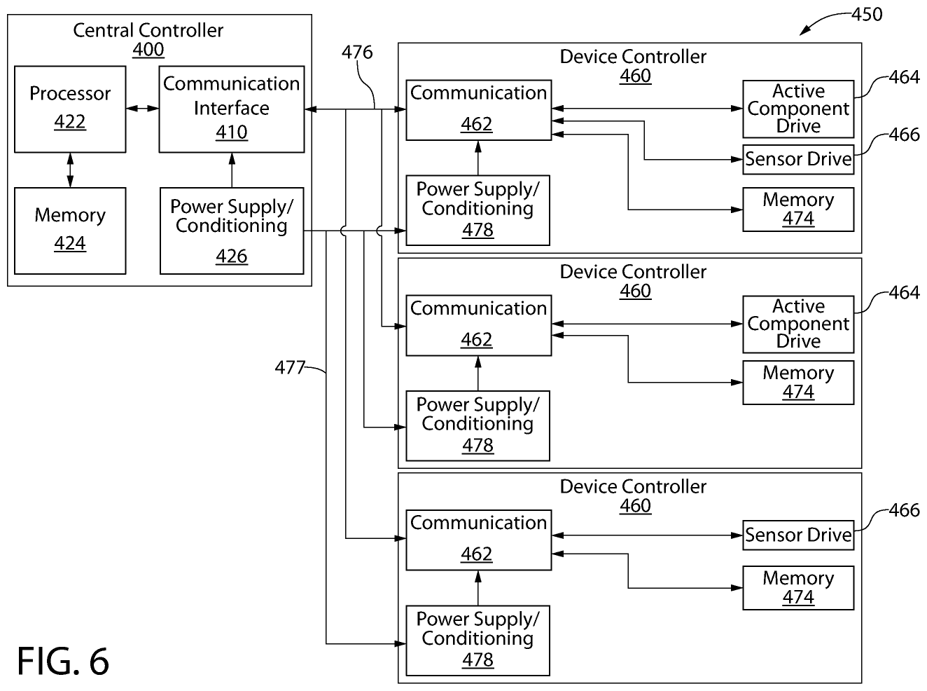

FIG. 6 further illustrates that, in some implementations, sensor data from multiple apparatus for controlling flow 100 may be used to control an active component of a single apparatus for controlling flow 100 or that sensor data from one apparatus for controlling flow 100 may be used to control an active component for a different apparatus for controlling flow 100. The controller 450 has a central controller 400 and a plurality of device controllers 460. The central controller 400 has a processor 422, a memory 424, a communication module 410, and a power supply/conditioning module 426. A communication bus 476 and a power connection 477 link the central controller 400 to the plurality of device controllers 460. Optionally, each of the device controllers 460 may not implement a processor. Calibration values for the sensors and active components may be stored in the memory 474.

A first one of the device controllers 460 may have a communication module 462, a memory 474, an active component drive 464, a sensor drive 466, and a power supply/conditioning module 478. A second one of the device controllers 460 may have a communication module 462, a memory 474, an active component drive 464, and a power supply/conditioning module 478. A third one of the device controllers 460 may have a communication module 462, a memory 474, a sensor drive 466, and a power supply/conditioning module 478. Each of the first, second, and third device controllers 460 may operate a first, second, and third apparatus for controlling flow 100.

Thus, the second device controller 460 may only control an active component via the active component drive 464 and the corresponding apparatus for controlling flow 100 may lack a sensor. Similarly, the third device controller 460 may only have a sensor drive which generates sensor data from a sensor of the corresponding apparatus for controlling flow 100. The apparatus for controlling flow 100 coupled to the third device controller may lack an active component. Sensor data from the first and third device controllers 460 may be used by the central controller 400 to compute active component commands for the first and second apparatus for controlling flow 100. These active component commands may be implemented by their associated device controllers 460.

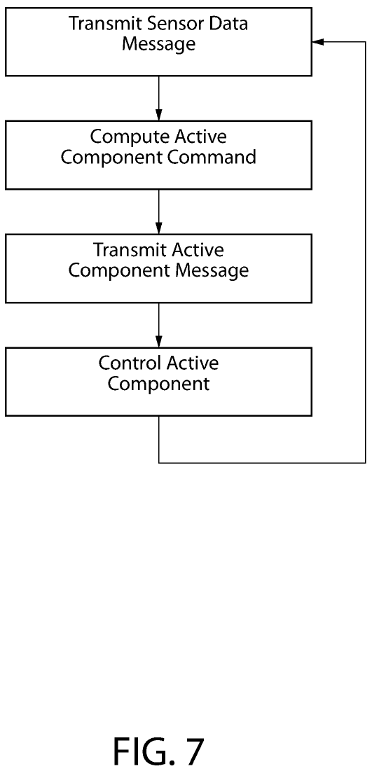

Turning to FIG. 7, a method of manufacturing semiconductors is illustrated. In a first step, a first sensor data message is transmitted from a device controller of a first apparatus for controlling flow to a central controller. The first sensor data message includes first sensor data. The first apparatus for controlling flow has a sensor operably coupled to the device controller, the first sensor data generated by the sensor. The sensor senses a characteristic of a fluid within a fluid pathway of the first apparatus for controlling flow.

In a second step, a first active component command is computed using a setpoint stored in a memory of the central controller and the first sensor data of the first sensor data message. In a third step, a first active component message is transmitted from the central controller to the device controller of the first apparatus for controlling flow. The first active component message includes the first active component command.

In a fourth step, an active component of the first apparatus for controlling flow is controlled in accordance with the first active component command. This causes the first apparatus for controlling flow to deliver the fluid to a processing chamber containing an article to be processed. In a fifth step, the process repeats such that a second sensor data message containing second sensor data is transmitted from the device controller of the first apparatus for controlling flow to the central controller.

In a sixth step, a second active component command is computed using the setpoint and the second sensor data. In a seventh step, a second active component message is transmitted from the central controller to the device controller of the first apparatus for controlling flow. The second active component message contains the second active component command. In an eighth step, the active component is controlled in accordance with the second active component command to deliver the fluid to the processing chamber.

Thus, a feedback control loop is implemented in the central controller, with the central controller commanding the active component of the apparatus for controlling flow based on the sensor data and the setpoint stored in the central controller. The setpoint corresponds to a target operating parameter of the first apparatus for controlling flow. For example, if the apparatus for controlling flow is a mass flow controller 101, the setpoint may correspond to a desired mass flow rate delivered by the mass flow controller 101.

It is further contemplated that a third sensor data message containing third sensor data may be transmitted from a device controller of a second apparatus for controlling flow to the central controller. Then, a third active component command may be computed using the setpoint and the third sensor data. The third active component command may be transmitted from the central controller to the device controller of the first apparatus for controlling flow in a third active component message. The active component of the first apparatus for controlling flow may then be controlled using the third active component command. This enables a first apparatus for controlling flow to alter its delivered flow based on sensor data from a second apparatus for controlling flow.

In yet another potential configuration, a fourth sensor data message containing fourth sensor data may be transmitted from a device controller of the second apparatus for controlling flow to the central controller. A fifth sensor data message containing fifth sensor data may also be transmitted from the device controller of the first apparatus for controlling flow to the central controller. A fourth active component command may be computed using the setpoint and the fourth and fifth sensor data. A fourth active component message may be transmitted from the central controller to the device controller of the first apparatus for controlling flow. The fourth active component message may contain the fourth active component command. The active component may then be controlled in accordance with the fourth active component command to deliver the fluid to the processing chamber

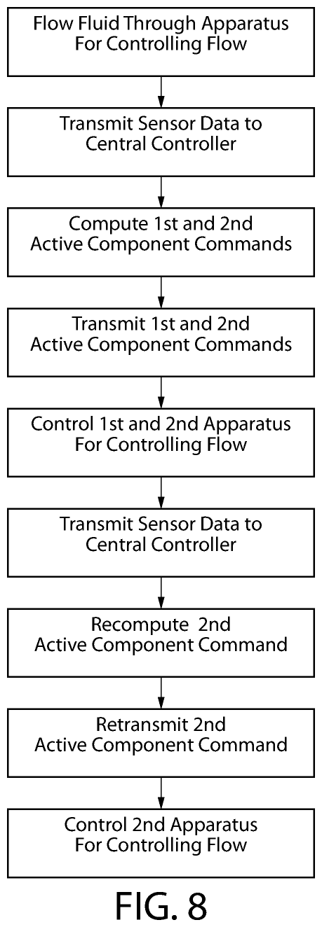

As illustrated in FIG. 8, another method of manufacturing semiconductors is illustrated. In a first step, a first fluid is flowed through a first apparatus for controlling flow and a second fluid is flowed through a second apparatus for controlling flow. The first and second fluids are delivered from the first and second apparatus for controlling flow to a processing chamber containing an article to be processed. In a second step, first and second sensor data from the first and second apparatus for controlling flow is transmitted to a central controller. The first and second sensor data are indicative of a characteristic of the first and second fluids flowing through the first and second apparatus for controlling flow.

In a third step, first and second active component commands are computed in the central controller using the first and second sensor data. In a fourth step, the first and second active component commands are transmitted from the central controller to the first and second apparatus for controlling flow. In a fifth step, active components of the first and second apparatus for controlling flow are controlled in accordance with the first and second active component commands.

In a sixth step, first and second sensor data from the first and second apparatus for controlling flow is transmitted to the central controller. In a seventh step, the second active component command is recomputed using the first sensor data. In an eighth step, the second active component command is retransmitted from the central controller to the second apparatus for controlling flow. In a ninth step, the active component of the second apparatus for controlling flow is controlled in accordance with the second active component command. Thus, the method utilizes data from the sensor of the first apparatus for controlling flow to control the active component of the second apparatus for controlling flow.

### Exemplary Claim Set

Exemplary claim 1: A system for manufacturing semiconductors comprising: a central controller comprising a processor, a memory, and a communication module; a plurality of fluid supplies; a plurality of apparatus for controlling flow, each of the plurality of apparatus for controlling flow comprising: an inlet fluidly coupled to one of the plurality of fluid supplies; an outlet; a fluid pathway connecting the inlet to the outlet; a sensor fluidly coupled to the fluid pathway; an active component fluidly coupled to the fluid pathway; and a device controller comprising a communication module, a memory, a sensor circuit operably coupled to the sensor, and an active component drive operably coupled to the active component; and a processing chamber fluidly coupled to the outlets of the plurality of apparatus for controlling flow, the processing chamber configured to contain an article to be processed; wherein the central controller is configured to receive sensor data from the sensor circuit of a first one of the plurality of apparatus for controlling flow and transmit an active component command to the active component drive of the first one of the plurality of apparatus for controlling flow, the active component command computed based on the sensor data.

Exemplary claim 2: The system of exemplary claim 1 wherein the central controller provides closed loop control of the active component of the first one of the plurality of apparatus for controlling flow.

Exemplary claim 3: The system of exemplary claim 1 or exemplary claim 2 wherein the memory of the first one of the plurality of apparatus for controlling flow stores calibration data.

Exemplary claim 4: The system of any one of exemplary claims 1 to 3 wherein the sensor is one of a pressure sensor or a temperature sensor.

Exemplary claim 5: The system of any one of exemplary claims 1 to 4 wherein the active component is a proportional valve.

Exemplary claim 6: The system of any one of exemplary claims 1 to 5 wherein the central controller implements a feedback control loop using the sensor data to control the active component of the first one of the plurality of apparatus for controlling flow.

Exemplary claim 7: The system of exemplary claim 6 wherein the central controller implements a feedback control loop for each of the plurality of apparatus for controlling flow.

Exemplary claim 8: The system of any one of exemplary claims 1 to 7 wherein the memory of the central controller stores a setpoint, the setpoint corresponding to a target operating parameter of the first one of the plurality of apparatus for controlling flow.

Exemplary claim 9: The system of any one of exemplary claims 1 to 8 wherein the device controller of the first one of the plurality of apparatus for controlling flow is configured to transmit a sensor data message comprising the sensor data.

Exemplary claim 10: The system of any one of exemplary claims 1 to 9 further comprising a communication bus operatively connecting the communication module of the central controller and the communication module of the device controller of the first one of the plurality of apparatus for controlling flow.

Exemplary claim 11: The system of exemplary claim 10 wherein the plurality of apparatus for controlling flow communicate with the central controller via the EtherCAT protocol.

Exemplary claim 12: The system of exemplary claim 10 wherein the plurality of apparatus for controlling flow communicate with the central controller via one of Ethernet, Modbus, Profibus, Profinet, DeviceNet, CANbus, Fieldbus, OPC, MQTT, or BACnet.

Exemplary claim 13: The system of any one of exemplary claims 1 to 12 wherein the central controller is configured to receive sensor data from the sensor circuit of a second one of the plurality of apparatus for controlling flow and transmit an active component command to the active component drive of the second one of the plurality of apparatus for controlling flow.

Exemplary claim 14: The system of exemplary claim 13 wherein the active component command transmitted to the first one of the plurality of apparatus for controlling flow is computed at least in part based on sensor data of the second one of the plurality of apparatus for controlling flow.

Exemplary claim 15: The system of any one of exemplary claims 1 to 14 wherein the active component command is computed based on a setpoint stored in the memory of the central controller.

Exemplary claim 16: A system for manufacturing semiconductors comprising: a central controller comprising a processor, a memory, and a communication module; a fluid supply; a first apparatus for controlling flow comprising: an inlet fluidly coupled to the fluid supply; an outlet; a fluid pathway connecting the inlet to the outlet; a sensor fluidly coupled to the fluid pathway; an active component fluidly coupled to the fluid pathway; and a device controller comprising a communication module, a memory, a sensor circuit operably coupled to the sensor, and an active component drive operably coupled to the active component; a processing chamber fluidly coupled to the outlet of the first apparatus for controlling flow, the processing chamber configured to contain an article to be processed; and a communication bus operatively connecting the communication module of the central controller and the communication module of the device controller; wherein the device controller is configured to transmit a sensor data message comprising sensor data to the central controller via the communication bus; and wherein the central controller is configured to transmit an active component message to the device controller via the communication bus, the active component message comprising an active component command determined at least in part based on a setpoint stored in the memory of the central controller and on the sensor data of the sensor data message.

Exemplary claim 17: The system of exemplary claim 16 wherein the central controller provides closed loop control of the active component of the first apparatus for controlling flow.

Exemplary claim 18: The system of exemplary claim 16 or exemplary claim 17 wherein the memory of the first apparatus for controlling flow stores calibration data.

Exemplary claim 19: The system of any one of exemplary claims 16 to 18 wherein the sensor is one of a pressure sensor or a temperature sensor.

Exemplary claim 20: The system of any one of exemplary claims 16 to 19 wherein the active component is a proportional valve.

Exemplary claim 21: The system of any one of exemplary claims 16 to 20 wherein the central controller implements a feedback control loop using the sensor data to control the active component of the first apparatus for controlling flow.

Exemplary claim 22: The system of exemplary claim 21 wherein the central controller implements a feedback control loop for the first apparatus for controlling flow.

Exemplary claim 23: The system of any one of exemplary claims 16 to 22 wherein the setpoint corresponds to a target operating parameter of the first apparatus for controlling flow.

Exemplary claim 24: The system of any one of exemplary claims 16 to 23 wherein the first apparatus for controlling flow communicates with the central controller via the EtherCAT protocol.

Exemplary claim 25: The system of any one of exemplary claims 16 to 23 wherein the first apparatus for controlling flow communicates with the central controller via one of Ethernet, Modbus, Profibus, Profinet, DeviceNet, CANbus, Fieldbus, OPC, MQTT, or BACnet.

Exemplary claim 26: The system of any one of exemplary claims 16 to 25 wherein the central controller is configured to receive sensor data from a sensor circuit of a second apparatus for controlling flow and transmit an active component command to an active component drive of the second apparatus for controlling flow.

Exemplary claim 27: The system of exemplary claim 26 wherein the active component command transmitted to the first apparatus for controlling flow is computed at least in part based on sensor data of the second apparatus for controlling flow.

Exemplary claim 28: A system for manufacturing semiconductors comprising: a central controller comprising a processor, a memory, and a communication module; a fluid supply; a first apparatus for controlling flow comprising: an inlet fluidly coupled to the fluid supply; an outlet; a fluid pathway connecting the inlet to the outlet; a sensor fluidly coupled to the fluid pathway; and an active component fluidly coupled to the fluid pathway; and a device controller comprising a communication module, a memory, a sensor circuit operably coupled to the sensor, and an active component drive operably coupled to the active component; a processing chamber fluidly coupled to the outlet of the first apparatus for controlling flow, the processing chamber configured to contain an article to be processed; and a communication bus operatively connecting the communication module of the central controller and the communication module of the device controller; wherein the central controller implements a feedback control loop utilizing sensor data from the first apparatus for controlling flow to control the active component of the first apparatus for controlling flow.

Exemplary claim 29: The system of exemplary claim 28 wherein the memory of the first apparatus for controlling flow stores calibration data.

Exemplary claim 30: The system of exemplary claim 28 or exemplary claim 29 wherein the sensor is one of a pressure transducer or a temperature sensor.

Exemplary claim 31: The system of any one of exemplary claims 28 to 30 wherein the active component is a proportional valve.

Exemplary claim 32: The system of any one of exemplary claims 28 to 31 wherein the memory of the central controller stores a setpoint, the setpoint corresponding to a target operating parameter of the first apparatus for controlling flow.

Exemplary claim 33: The system of any one of exemplary claims 28 to 32 wherein the device controller of the first apparatus for controlling flow is configured to transmit a sensor data message comprising the sensor data.

Exemplary claim 34: The system of any one of exemplary claims 28 to 33 wherein the first apparatus for controlling flow communicates with the central controller via the EtherCAT protocol.

Exemplary claim 35: The system of any one of exemplary claims 28 to 33 wherein the plurality of apparatus for controlling flow communicate with the central controller via one of Ethernet, Modbus, Profibus, Profinet, DeviceNet, CANbus, Fieldbus, OPC, MQTT, or BACnet.

Exemplary claim 36: The system of any one of claims 28 to 35 wherein the central controller is configured to receive sensor data from the sensor circuit of a second apparatus for controlling flow and transmit an active component command to the active component drive of the second apparatus for controlling flow.

Exemplary claim 37: The system of any one of exemplary claims 28 to 36 wherein the active component command transmitted to the first apparatus for controlling flow is computed at least in part based on sensor data of the second apparatus for controlling flow.

Exemplary claim 38: The system of any one of exemplary claims 28 to 37 wherein the active component command is computed based on a setpoint stored in the memory of the central controller.

Exemplary claim 39: A method of manufacturing semiconductors comprising: a) transmitting a first sensor data message comprising first sensor data from a device controller of a first apparatus for controlling flow to a central controller, the first apparatus for controlling flow comprising a sensor operably coupled to the device controller, the sensor sensing a characteristic of a fluid within a fluid pathway of the first apparatus for controlling flow; b) computing a first active component command using a setpoint stored in a memory of the central controller and the first sensor data of the first sensor data message; c) transmitting a first active component message from the central controller to the device controller of the first apparatus for controlling flow, the first active component message comprising the first active component command; d) controlling an active component of the first apparatus for controlling flow in accordance with the first active component command to deliver the fluid to a processing chamber comprising an article to be processed; c) transmitting a second sensor data message comprising second sensor data from the device controller of the first apparatus for controlling flow to the central controller; f) computing a second active component command using the setpoint and the second sensor data; g) transmitting a second active component message from the central controller to the device controller of the first apparatus for controlling flow, the second active component message comprising the second active component command; h) controlling the active component in accordance with the second active component command to deliver the fluid to the processing chamber.

Exemplary claim 40: The method of exemplary claim 39 wherein steps a) through
h) implement a feedback control loop in the central controller which controls the active component of the first apparatus for controlling flow.

Exemplary claim 41: The method of exemplary claim 39 or exemplary claim 40 wherein the active component is a proportional valve.

Exemplary claim 42: The method of any one of exemplary claims 39 to 41 wherein the apparatus for controlling flow is a mass flow controller.

Exemplary claim 43: The method of any one of exemplary claims 39 to 42 wherein the sensor is one of a pressure sensor or a temperature sensor.

Exemplary claim 44: The method of any one of exemplary claims 39 to 43 wherein the setpoint corresponds to a target operating parameter of the first apparatus for controlling flow.

Exemplary claim 45: The method of any one of exemplary claims 39 to 44 wherein the first apparatus for controlling flow communicates with the central controller via the EtherCAT protocol.

Exemplary claim 46: The method of any one of exemplary claims 39 to 44 wherein the first apparatus for controlling flow communicates with the central controller via one of Ethernet, Modbus, Profibus, Profinet, DeviceNet, CANbus, Fieldbus, OPC, MQTT, or BACnet.

Exemplary claim 47: The method of any one of exemplary claims 39 to 46 further comprising steps i), j), k), and l), step i) comprising transmitting a third sensor data message comprising third sensor data from a device controller of a second apparatus for controlling flow to the central controller, step j) comprising computing a third active component command using the setpoint and the third sensor data, step k) comprising transmitting a third active component message from the central controller to the device controller of the first apparatus for controlling flow, the third active component message comprising the third active component command, and step 1) comprising controlling the active component in accordance with the third active component command to deliver the fluid to the processing chamber.

Exemplary claim 48: The method of any one of exemplary claims 39 to 46 further comprising steps i), j), k), and l), step i) comprising transmitting a fourth sensor data message comprising fourth sensor data from a device controller of a second apparatus for controlling flow to the central controller and transmitting a fifth sensor data message comprising fifth sensor data from the device controller of the first apparatus for controlling flow to the central controller, step j) comprising computing a fourth active component command using the setpoint and the fourth and fifth sensor data, step k) comprising transmitting a fourth active component message from the central controller to the device controller of the first apparatus for controlling flow, the fourth active component message comprising the fourth active component command, and step l) comprising controlling the active component in accordance with the fourth active component command to deliver the fluid to the processing chamber.

Exemplary claim 49: A system for manufacturing semiconductors comprising: a central controller comprising a processor, a memory, and a communication module; a fluid supply; a first apparatus for controlling flow comprising: an inlet fluidly coupled to the fluid supply; an outlet; a fluid pathway connecting the inlet to the outlet; a sensor fluidly coupled to the fluid pathway; and a device controller comprising a communication module, a memory, and a sensor circuit operably coupled to the sensor; a second apparatus for controlling flow comprising: an inlet fluidly coupled to the fluid supply; an outlet; a fluid pathway connecting the inlet to the outlet; an active component fluidly coupled to the fluid pathway; and a device controller comprising a communication module, a memory, and an active component drive operably coupled to the active component; a processing chamber fluidly coupled to the outlet of the first and second apparatus for controlling flow, the processing chamber configured to contain an article to be processed; and wherein the device controller of the first apparatus for controlling flow is configured to transmit a sensor data message comprising sensor data to the central controller; and wherein the central controller is configured to transmit an active component message to the device controller of the second apparatus for controlling flow, the active component message comprising an active component command determined at least in part based on a setpoint stored in the memory of the central controller and on the sensor data of the sensor data message.

Exemplary claim 50: The system of exemplary claim 49 wherein the sensor is one of a pressure sensor or a temperature sensor.

Exemplary claim 51: The system of exemplary claim 49 or exemplary claim 50 wherein the active component is a proportional valve.

Exemplary claim 52: The system of any one of exemplary claims 49 to 51 wherein the central controller provides closed loop control of the active component of the second apparatus for controlling flow using sensor data from the first apparatus for controlling flow.

Exemplary claim 53: The system of any one of exemplary claims 49 to 52 wherein the central controller implements a feedback control loop.

Exemplary claim 54: The system of any one of exemplary claims 49 to 53 further comprising a communication bus operatively connecting the communication module of the central controller and the communication module of the device controller of the first one of the plurality of apparatus for controlling flow.

Exemplary claim 55: The system of any one of exemplary claims 49 to 54 wherein the first and second apparatus for controlling flow communicate with the central controller via the EtherCAT protocol.

Exemplary claim 56: The system of any one of exemplary claims 49 to 54 wherein the first and second apparatus for controlling flow communicate with the central controller via one of Ethernet, Modbus, Profibus, Profinet, DeviceNet, CANbus, Fieldbus, OPC, MQTT, or BACnet.

Exemplary claim 57: A method of manufacturing semiconductors comprising: a) flowing a first fluid through a first apparatus for controlling flow and a second fluid through a second apparatus for controlling flow, the first and second fluids delivered from the first and second apparatus for controlling flow to a processing chamber containing an article to be processed; b) transmitting first and second sensor data from the first and second apparatus for controlling flow to a central controller, the first and second sensor data indicative of a characteristic of the first and second fluids flowing through the first and second apparatus for controlling flow; c) computing first and second active component commands in the central controller using the first and second sensor data; d) transmitting the first and second active component commands from the central controller to the first and second apparatus for controlling flow; c) controlling active components of the first and second apparatus for controlling flow in accordance with the first and second active component commands; f) transmitting first and second sensor data from the first and second apparatus for controlling flow to the central controller; g) recomputing the second active component command using the first sensor data; h) retransmitting the second active component command from the central controller to the second apparatus for controlling flow; i) controlling the active component of the second apparatus for controlling flow in accordance with the second active component command.

Exemplary claim 58: The method of exemplary claim 57 wherein the first and second apparatus for controlling flow are mass flow controllers.

Exemplary claim 59: The method of exemplary claim 57 or exemplary claim 58 wherein the characteristic of the first and second fluids is one of pressure or temperature.

Exemplary claim 60: The method of any one of exemplary claims 57 to 59 wherein step c) further comprises computing the first and second active component commands based on first and second setpoints, the first and second setpoints corresponding to target mass flow rates for the first and second apparatus for controlling flow.

Exemplary claim 61: The method of any one of exemplary claims 57 to 60 wherein the first and second apparatus for controlling flow communicate with the central controller via the EtherCAT protocol.

Exemplary claim 62: The method of any one of exemplary claims 57 to 60 wherein the first and second apparatus for controlling flow communicate with the central controller via one of Ethernet, Modbus, Profibus, Profinet, DeviceNet, CANbus, Fieldbus, OPC, MQTT, or BACnet.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly as set forth in the appended claims.

1. A system for manufacturing semiconductors comprising:
a central controller comprising a processor, a memory, and a communication module;
a plurality of fluid supplies;
a plurality of apparatus for controlling flow, each of the plurality of apparatus for controlling flow comprising:
an inlet fluidly coupled to one of the plurality of fluid supplies;
an outlet;
a fluid pathway connecting the inlet to the outlet;
a sensor fluidly coupled to the fluid pathway;
an active component fluidly coupled to the fluid pathway; and
a device controller comprising a communication module, a memory, a sensor circuit operably coupled to the sensor, and an active component drive operably coupled to the active component; and
a processing chamber fluidly coupled to the outlets of the plurality of apparatus for controlling flow, the processing chamber configured to contain an article to be processed;
wherein the central controller is configured to receive sensor data from the sensor circuit of a first one of the plurality of apparatus for controlling flow and transmit an active component command to the active component drive of the first one of the plurality of apparatus for controlling flow, the active component command computed based on the sensor data.

2. The system of claim 1 wherein the central controller provides closed loop control of the active component of the first one of the plurality of apparatus for controlling flow.

3. The system of claim 1 wherein the memory of the first one of the plurality of apparatus for controlling flow stores calibration data.

4. The system of claim 1 wherein the sensor is one of a pressure sensor or a temperature sensor and wherein the active component is a proportional valve.

5. (canceled)

6. The system of claim 1 wherein the central controller implements a feedback control loop using the sensor data to control the active component of the first one of the plurality of apparatus for controlling flow and wherein the central controller implements a feedback control loop for each of the plurality of apparatus for controlling flow.

7. (canceled)

8. The system of claim 1 wherein the memory of the central controller stores a setpoint, the setpoint corresponding to a target operating parameter of the first one of the plurality of apparatus for controlling flow.

9. The system of claim 1 wherein the device controller of the first one of the plurality of apparatus for controlling flow is configured to transmit a sensor data message comprising the sensor data.

10. The system of claim 1 further comprising a communication bus operatively connecting the communication module of the central controller and the communication module of the device controller of the first one of the plurality of apparatus for controlling flow.

11. The system of claim 10 wherein the plurality of apparatus for controlling flow communicate with the central controller via the EtherCAT protocol.

12. The system of claim 10 wherein the plurality of apparatus for controlling flow communicate with the central controller via one of Ethernet, Modbus, Profibus, Profinet, DeviceNet, CANbus, Fieldbus, OPC, MQTT, or BACnet.

13. The system of claim 1 wherein the central controller is configured to receive sensor data from the sensor circuit of a second one of the plurality of apparatus for controlling flow and transmit an active component command to the active component drive of the second one of the plurality of apparatus for controlling flow and wherein the active component command transmitted to the first one of the plurality of apparatus for controlling flow is computed at least in part based on sensor data of the second one of the plurality of apparatus for controlling flow.

14. (canceled)

15. The system of claim 1 wherein the active component command is computed based on a setpoint stored in the memory of the central controller.

16. A system for manufacturing semiconductors comprising:
a central controller comprising a processor, a memory, and a communication module;
a fluid supply;
a first apparatus for controlling flow comprising:
an inlet fluidly coupled to the fluid supply;
an outlet;
a fluid pathway connecting the inlet to the outlet;
a sensor fluidly coupled to the fluid pathway;
an active component fluidly coupled to the fluid pathway; and
a device controller comprising a communication module, a memory, a sensor circuit operably coupled to the sensor, and an active component drive operably coupled to the active component;
a processing chamber fluidly coupled to the outlet of the first apparatus for controlling flow, the processing chamber configured to contain an article to be processed; and
a communication bus operatively connecting the communication module of the central controller and the communication module of the device controller;
wherein the device controller is configured to transmit a sensor data message comprising sensor data to the central controller via the communication bus; and
wherein the central controller is configured to transmit an active component message to the device controller via the communication bus, the active component message comprising an active component command determined at least in part based on a setpoint stored in the memory of the central controller and on the sensor data of the sensor data message.

17.-20. (canceled)

21. The system of claim 16 wherein the central controller implements a feedback control loop using the sensor data to control the active component of the first apparatus for controlling flow.

22. (canceled)

23. The system of claim 16 wherein the setpoint corresponds to a target operating parameter of the first apparatus for controlling flow.

24. (canceled)

25. (canceled)

26. The system of claim 16 wherein the central controller is configured to receive sensor data from a sensor circuit of a second apparatus for controlling flow and transmit an active component command to an active component drive of the second apparatus for controlling flow.

27. The system of claim 26 wherein the active component command transmitted to the first apparatus for controlling flow is computed at least in part based on sensor data of the second apparatus for controlling flow.

28.-38. (canceled)

39. A method of manufacturing semiconductors comprising:
a) transmitting a first sensor data message comprising first sensor data from a device controller of a first apparatus for controlling flow to a central controller, the first apparatus for controlling flow comprising a sensor operably coupled to the device controller, the sensor sensing a characteristic of a fluid within a fluid pathway of the first apparatus for controlling flow;
b) computing a first active component command using a setpoint stored in a memory of the central controller and the first sensor data of the first sensor data message;
c) transmitting a first active component message from the central controller to the device controller of the first apparatus for controlling flow, the first active component message comprising the first active component command;
d) controlling an active component of the first apparatus for controlling flow in accordance with the first active component command to deliver the fluid to a processing chamber comprising an article to be processed;
e) transmitting a second sensor data message comprising second sensor data from the device controller of the first apparatus for controlling flow to the central controller;
f) computing a second active component command using the setpoint and the second sensor data;
g) transmitting a second active component message from the central controller to the device controller of the first apparatus for controlling flow, the second active component message comprising the second active component command;
h) controlling the active component in accordance with the second active component command to deliver the fluid to the processing chamber.

40.-46. (canceled)

47. The method of claim 39 further comprising steps i), j), k), and l), step i) comprising transmitting a third sensor data message comprising third sensor data from a device controller of a second apparatus for controlling flow to the central controller, step j) comprising computing a third active component command using the setpoint and the third sensor data, step k) comprising transmitting a third active component message from the central controller to the device controller of the first apparatus for controlling flow, the third active component message comprising the third active component command, and step l) comprising controlling the active component in accordance with the third active component command to deliver the fluid to the processing chamber.

48. The method of claim 39 further comprising steps i), j), k), and l), step i) comprising transmitting a fourth sensor data message comprising fourth sensor data from a device controller of a second apparatus for controlling flow to the central controller and transmitting a fifth sensor data message comprising fifth sensor data from the device controller of the first apparatus for controlling flow to the central controller, step j) comprising computing a fourth active component command using the setpoint and the fourth and fifth sensor data, step k) comprising transmitting a fourth active component message from the central controller to the device controller of the first apparatus for controlling flow, the fourth active component message comprising the fourth active component command, and step l) comprising controlling the active component in accordance with the fourth active component command to deliver the fluid to the processing chamber.

49.-62. (canceled)
